(19) United States
(12) Patent Application Publication
(10) Pub. No.: US 2006/0278520 A1
(43) Pub. Date: Dec. 14, 2006

(54) Use of DC magnetron sputtering systems

(76) Inventors: Eal H. Lee, Milpitas, CA (US); Robert M. Prater, Los Altos, CA (US); Nicole M. Truong, Milpitas, CA (US); Jaeyeon Kim, Liberty Lake, WA (US)

Correspondence Address: BINGHAM, MCCUTCHEN LLP, THREE EMBARCADERO CENTER, 18 FLOOR, SAN FRANCISCO, CA, 94111-4067, US

(21) Appl. No.: 11/150,900

(22) Filed: Jun. 13, 2005

(51) Int. Cl. C23C 14/32; C23C 14/00

(52) U.S. Cl. 204/192.1; 204/298.16

(57) ABSTRACT

A DC magnetron sputtering system is described that comprises an anodic shield; a cathodic target that comprises at least one sidewall; a plasma ignition arc; and a catch-ring coupled to and located around the shield. Another DC magnetron sputtering system is described that comprises an anodic shield; a cathodic target comprising at least one recess, cavity or a combination thereof and at least one protrusion; and a plasma ignition arc, whereby the arc is located at the point of least resistance between the anodic shield and the at least one recess, cavity or a combination thereof, the at least one protrusion or a combination thereof. Yet another DC magnetron sputtering system is described herein that comprises an anodic shield comprising at least one protrusion; a cathodic target comprising at least one recess, cavity or a combination thereof; and a plasma ignition arc, whereby the arc is located at the point of least resistance between the at least one protrusion coupled to the anodic shield and the at least one protrusion, recess or cavity. Methods are also provided whereby the gas turbulence effect is mitigated, such methods including providing an anodic shield; providing a cathodic target comprising at least one recess, cavity or a combination thereof and at least one protrusion; and initiating a plasma ignition arc, whereby the arc is located at the point of least resistance between the anodic shield and the at least one recess, cavity or a combination thereof, the at least one protrusion or a combination thereof. Additional methods include providing an anodic shield; providing a cathodic target that comprises at least one sidewall; providing a catch-ring coupled to and around the shield; and initiating a plasma ignition arc.

### FIELD OF THE INVENTION

The field of the invention is the design and use of DC magnetron sputtering systems, including particle catch-rings and reduction of particle generation in these systems.

### BACKGROUND

Electronic and semiconductor components are used in ever-increasing numbers of consumer and commercial electronic products, communications products and data-exchange products. Examples of some of these consumer and commercial products are televisions, computers, cell phones, pagers, palm-type or handheld organizers, portable radios, car stereos, or remote controls. As the demand for these consumer and commercial electronics increases, there is also a demand for those same products to become smaller and more portable for the consumers and businesses.

As a result of the size decrease in these products, the components that comprise the products must also become smaller and/or thinner. Examples of some of those components that need to be reduced in size or scaled down are microelectronic chip interconnections, semiconductor chip components, resistors, capacitors, printed circuit or wiring boards, wiring, keyboards, touch pads, and chip packaging.

When electronic and semiconductor components are reduced in size or scaled down, any defects that are present in the larger components are going to be exaggerated in the scaled down components. Thus, the defects that are present or could be present in the larger component should be identified and corrected, if possible, before the component is scaled down for the smaller electronic products.

In order to identify and correct defects in electronic, semiconductor and communications components, the components, the materials used and the manufacturing processes for making those components should be broken down and analyzed. Electronic, semiconductor and communication/data-exchange components are composed, in some cases, of layers of materials, such as metals, metal alloys, ceramics, inorganic materials, polymers, or organometallic materials. The layers of materials are often thin (on the order of less than a few tens of angstroms in thickness). In order to improve on the quality of the layers of materials, the process of forming the layer—such as physical vapor deposition of a metal or other compound—should be evaluated and, if possible, modified and improved.

In order to improve the process of depositing a layer of material, the surface and/or material composition must be measured, quantified and defects or imperfections detected. In the case of the deposition of a layer or layers of material, its not the actual layer or layers of material that should be monitored but the material and surface of that material that is being used to produce the layer of material on a substrate or other surface. For example, when depositing a layer of metal onto a surface or substrate by sputtering a target comprising that metal, the atoms and molecules being deflected or liberated from the target must travel a path to the substrate or other surface that will allow for an even and uniform deposition. Atoms and molecules traveling natural and expected paths after deflection and/or liberation from the target will uneven deposition on the surface or substrate, including trenches and holes in the surface or substrate. For certain surfaces and substrates, it may be necessary to redirect the atoms and molecules leaving the target in order to achieve a more uniform deposition, coating and/or film on the surface or substrate.

In a DC magnetron sputtering system, deposition begins with plasma ignition that is triggered by electrical arcing between an anodic shield and a cathodic target. Particles are always generated during arcing and become a major source of defects responsible for the reduced yield in microelectronic chip fabrication. The strike arc induced particles are ejected at a high velocity, like shot gun pellets, guided by the gap between the shield and the target side wall. These particles not only land on the wafer surface, but their impact also causes severe plowing and chipping on the wafer, predominately on the outer edges of the wafer's top surface, producing additional particles, particularly silicon and oxygen containing particles. Some of the small airborne particles stick to the target and surrounding surfaces becoming additional arc sites, further negatively impacting yield management. To this end, it would be desirable to develop and utilize a deposition apparatus and sputtering chamber system that will maximize uniformity of the coating, film or deposition on a surface and/or substrate.

Infineon and AMAT observed (1) excessive arcing marks around the bottom corner area of a target sidewall and (2) rubbing marks on the backing plate outside of the O-ring. They machined away these problem areas to remove arcing sites (not to redirect arcing sites) and to prevent the backing plate from rubbing the ceramic ring. This modification leads serendipitously to some improvement in particle reduction. However, there are some drawbacks to the modified design, including: a) the design concept is not based on the physics of arcing, so the design optimization is not realized; b) the sloped target sidewall acts as reflective plane for the strike-arc induced particles, redirecting some of the particles toward the wafer; c) the target edge cools faster than the center due to the lower plasma density at the edge and the conductive medium underneath, so sputter atoms condense easily on the edge causing nodule formation; d) although a ledge is introduced by machining the backing plate, the positive slope results in inefficient strike-arc sites (i.e., less sharp, lower electric potential field); and e) the gradual change of the positive slope and somewhat shallow trench depth make a poorly defined demarcation between arcing and non-arcing area.

After reviewing the conventional target designs and the Infineon and AMAT modifications, it is clear that additional and more strategic modifications should be made to the targets to reduce particles. Modified targets a) should be designed based on the physics of arcing, so the design optimization is realized; b) should have a modified target sidewall that does not merely act as reflective plane for the strike-arc induced particles redirecting some of the particles toward the wafer; c) should have a target edge that has a cooling pattern similar to the center, so sputter atoms do not condense easily on the edge causing nodule formation; d) any modification should result in efficient strike-arc sites (i.e., less sharp, lower electric potential field); and e) the modification should result in a defined demarcation between the arcing and non-arcing area.

### SUMMARY OF THE SUBJECT MATTER

A DC magnetron sputtering system is described that comprises an anodic shield; a cathodic target that comprises at least one sidewall; a plasma ignition arc; and a catch-ring coupled to and located around the shield.

Another DC magnetron sputtering system is also described that comprises an anodic shield; a cathodic target comprising at least one recess, cavity or a combination thereof and at least one protrusion; and a plasma ignition arc, whereby the arc is located at the point of least resistance between the anodic shield and the at least one recess, cavity or a combination thereof, the at least one protrusion or a combination thereof.

Yet another DC magnetron sputtering system is described herein that comprises an anodic shield comprising at least one protrusion; a cathodic target comprising at least one recess, cavity or a combination thereof; and a plasma ignition arc, whereby the arc is located at the point of least resistance between the at least one protrusion coupled to the anodic shield and the at least one protrusion, recess or cavity.

Methods are also provided whereby the gas turbulence effect is mitigated, such methods including providing an anodic shield; providing a cathodic target comprising at least one recess, cavity or a combination thereof and at least one protrusion; and initiating a plasma ignition arc, whereby the arc is located at the point of least resistance between the anodic shield and the at least one recess, cavity or a combination thereof, the at least one protrusion or a combination thereof.

Methods are also provided whereby the gas turbulence effect is mitigated, such methods include providing an anodic shield comprising at least one protrusion; providing a cathodic target comprising at least one recess, cavity or a combination thereof; and initiating a plasma ignition arc, whereby the arc is located at the point of least resistance between the at least one protrusion coupled to the anodic shield and the at least one protrusion, recess or cavity.

Additional methods include providing an anodic shield; providing a cathodic target that comprises at least one sidewall; providing a catch-ring coupled to and around the shield; and initiating a plasma ignition arc.

### BRIEF DESCRIPTION OF THE FIGURES

Prior Art FIG. 1 shows a conventional cathodic target/anodic shield arrangement.

FIG. 2 shows the conventional system from Prior Art FIG. 1 where a particle catch-ring is coupled to and located around the anodic shield.

FIG. 3A shows the results of a plasma that is initiated via arcing that inevitably produces particles.

FIG. 3B shows how strike-arc induced particles are arrested by incorporating a catch-ring system.

FIG. 4A shows a conventional target design that comprises a vent slot, as mentioned earlier.

FIG. 4B shows how the anodic shield is placed relative to the cathodic target in a conventional design and where the primary arcing sites are located.

FIG. 5A shows a contemplated cathodic target design where a recess and a protrusion are incorporated into the design.

FIG. 5B shows how the anodic shield is placed relative to the cathodic target in a contemplated design and how the primary arcing sites are relocated.

FIG. 6A shows a conventional target design that comprises a vent slot, as mentioned earlier.

FIG. 6B shows a contemplated cathodic target design where a recess and a protrusion are incorporated into the design.

FIG. 7A shows a conventional ENDURA™ Al target.

FIG. 7B shows a contemplated modification that will reduce arc-induced particle projectiles.

FIG. 8A shows another conventional target design.

FIG. 8B shows how a cavity, recess and protrusion can be incorporated in order to reduce arc-induced particle projectiles.

FIG. 9A shows a conventional IMP VECTRA™ Cu target design.

FIG. 9B shows a modified target design where an external voltage source is embedded in the target recess.

FIGS. 10A and 10B show additional perspective schematics of the cathodic target design having a trench and an external voltage source.

FIG. 11 shows a conventional HCM system. This Figure is courtesy of Novellus Systems, Inc.

FIG. 12A shows a simplified view of the conventional HCM system.

FIG. 12B shows the modified HCM system with the primary arcing site shifted.

FIGS. 13A-13C show how a conventional target can be machined to form a modified target.

FIG. 14 shows a modified target with a anodic shield having a protrusion.

### DESCRIPTION OF THE SUBJECT MATTER

As mentioned earlier, in a DC magnetron sputtering system, deposition begins with plasma ignition that is triggered by electrical arcing between an anodic shield and a cathodic target. Prior Art FIG. 1 shows a conventional cathode target 100/anodic shield 110 arrangement. The target and anode are connected to a DC power supply 105. In this conventional arrangement, a dense plasma 130 is formed around a magnetic field 120. The strike area 140 is also shown. Water 175 is directed into the system with the help of a rotary motor 190. In this embodiment, a silicon wafer 150 is placed in the chamber 180 on top of a heated gas line 170. Process gas 160 is added to the chamber and pumped out by pump 165.

Particles are always generated during arcing and become a major source of defects responsible for the reduced yield in microelectronic chip fabrication. The strike arc induced particles and/or plasma ignition particles are ejected at a high velocity, like shot gun pellets, guided by the gap between the shield and the target side wall. These particles not only land on the wafer surface, but their impact also causes severe plowing and chipping on the wafer, predominately on the outer edges of the wafer's top surface, producing additional particles, particularly silicon and oxygen containing particles. Some of the small airborne particles stick to the target and surrounding surfaces becoming additional arc sites, further negatively impacting yield management.

Prior research has focused on minimizing arcing effects by modifying the vent slot design, and this approach has yielded some success in mitigating the gas turbulence effect that triggers more violent arcing. In order to manage these defects, a deposition apparatus and sputtering chamber system has been developed that maximizes uniformity of the coating, film or deposition on a surface and/or substrate. More specifically, an apparatus and related method has surprisingly been developed that will address the gas turbulence effect in more detail. Modified targets described herein a) are designed based on the physics of arcing, so the design optimization is realized; b) have a modified target sidewall that does not merely act as reflective plane for the strike-arc induced particles redirecting some of the particles toward the wafer; c) have a target edge that has a cooling pattern similar to the center, so sputter atoms do not condense easily on the edge causing nodule formation; d) result in efficient strike-arc sites (i.e., less sharp, lower electric potential field); and e) result in a defined demarcation between the arcing and non-arcing area.

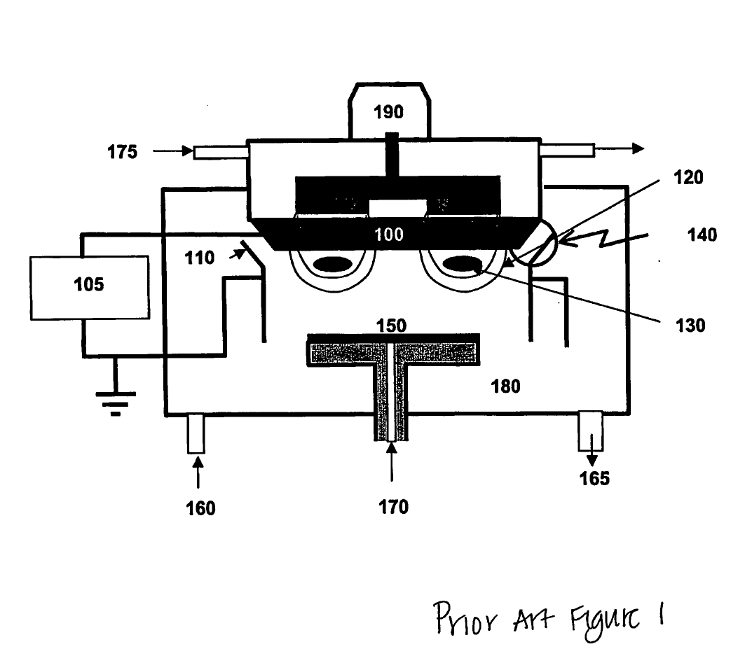

In one contemplated embodiment, a catch-ring is installed in the particle projectile path that will interact with the particles that are ejected from the arc start. In this embodiment, a DC magnetron sputtering system comprises an anodic shield; a cathodic target that comprises at least one sidewall; a plasma ignition arc; and a catch-ring coupled to and located around the shield. FIG. 2 shows the conventional system from Prior Art FIG. 1 where a particle catch-ring is coupled to and located around the anodic shield. The modified system in FIG. 2 shows a cathode target 200/anodic shield 210 arrangement. The target and anode are connected to a DC power supply 205. In this modified arrangement, a catch ring 245 is coupled to and located around the anode 210. As in the conventional system, water 275 is directed into the system with the help of a rotary motor 290. In this embodiment, a silicon wafer 250 is placed in the chamber 280 on top of a heated gas line 270. Process gas 260 is added to the chamber and pumped out by pump 265.

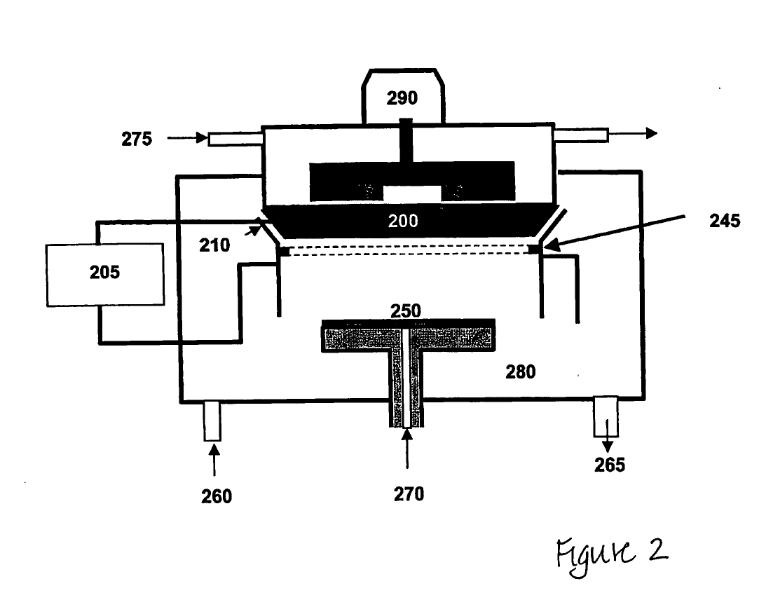

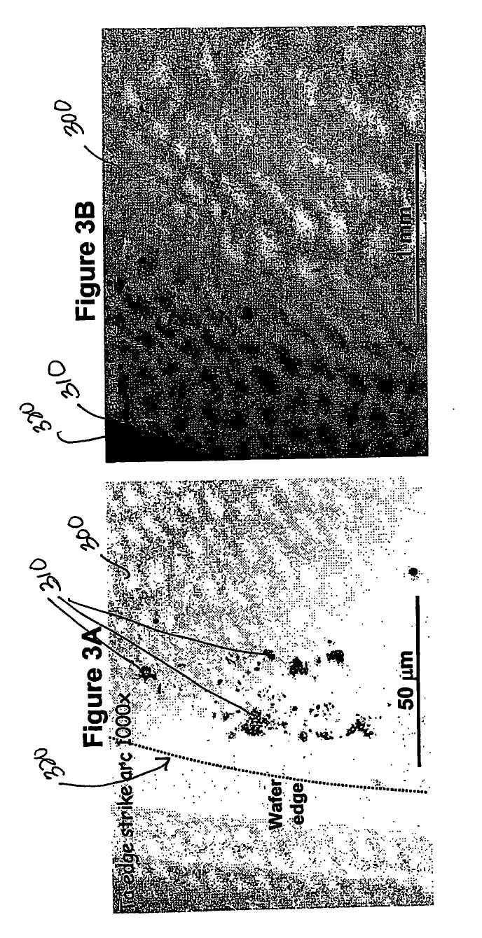

FIG. 3A shows the results of a plasma that is initiated via arcing that inevitably produces particles 310 on a wafer 300. The strike-arc induced particles 310 are mostly confined within a few mm of the wafer perimeter 320 because the particle ejection projectile is guided by the approximately 1 mm gap between the anodic shield and the cathodic target-sidewall. These particles 310 become subsequent arcing sites that contaminate the target and cause defects in the wafers. In recognition of this known particle ejection projectile path, particles can be arrested before reaching the wafer by placing a catch-ring around the shield in the particle projectile path. A particle catch-ring is coupled to and is placed around the anodic shield below the target. The position and placement of the ring is determined by the need to block the ejected particles but not to interfere the sputtered atoms. The width of a catch-ring is designed to allow about 1-3 mm overlap with the projection of the target's edge. The width of the ring can be increased as the ring is lowered away from the target. Typical ring width can be about 1 cm at about 2 cm below the target. Such an arrangement also extends the anodic field, so the plasma density near the edge of the target can be increased, resulting in reduced nodule formation around the edge of the target, particularly in nitriding process such as TaN and TiN. FIG. 3B shows how strike-arc induced particles 310 near the wafer edge 320 are arrested by incorporating a catch-ring system. The particles shown on the wafer 300 in this figure are mostly from a flaking shield that had reached a maintenance cycle. If the chamber had been clean, there would have been much fewer particles.

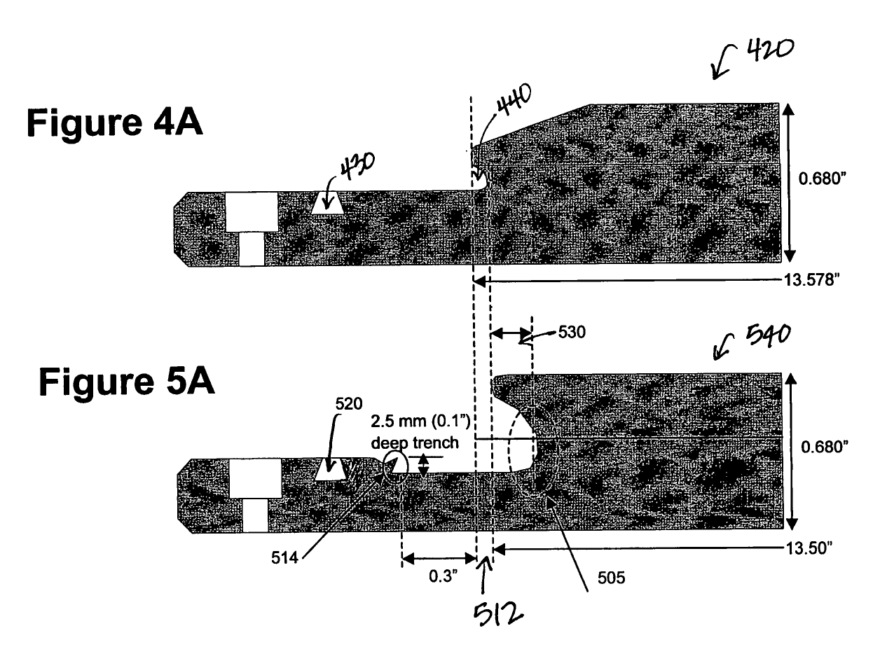

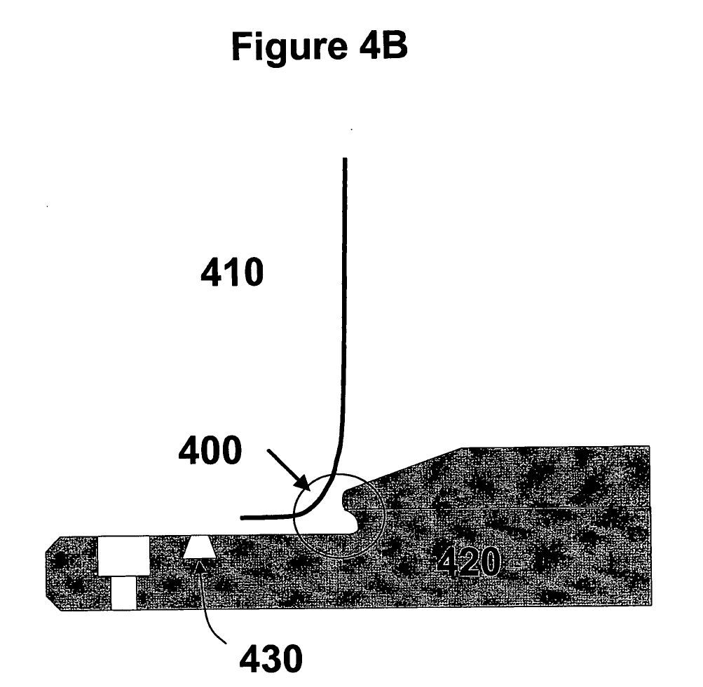

In another embodiment, the initial arc is located so as to direct the particles to areas that will minimize their damage to the microelectronic devices on the wafer. In this embodiment, a DC magnetron sputtering system comprises an anodic shield; a cathodic target comprising at least one recess, cavity or a combination thereof and at least one protrusion; and a plasma ignition arc, whereby the arc is located at the point of least resistance between the anodic shield and the at least one recess, cavity or a combination thereof, the at least one protrusion or a combination thereof. FIG. 4A shows a conventional target design 420 that comprises a vent slot 430 and a recess 440, as mentioned earlier. FIG. 4B shows how the anodic shield 410 is placed relative to the cathodic target 420 in a conventional design and where the primary arcing sites 400 are located.

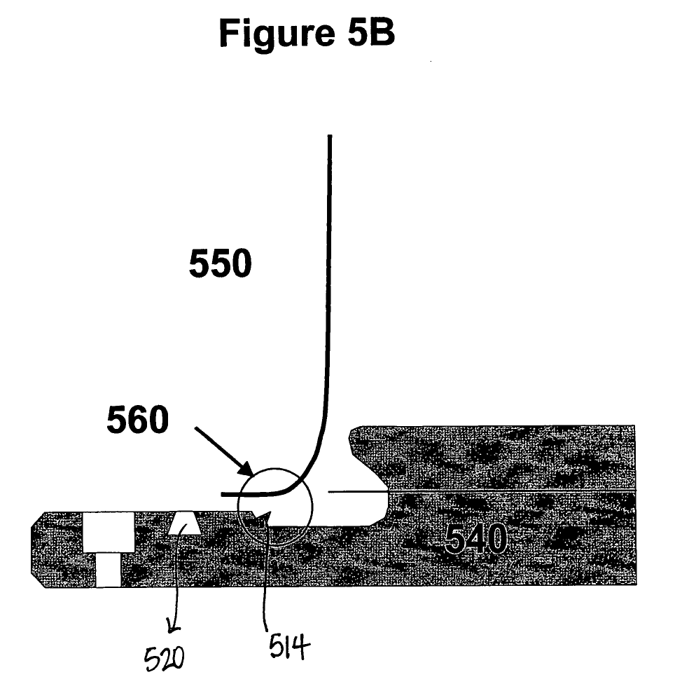

FIG. 5A shows a contemplated cathodic target design 540 having a vent slot 520 where a minimal recess 512, along with a protrusion 514, is incorporated into the design. The recess 510 in this embodiment is about 1 mm. Measurements 530 show that the depth of the recess in the modified cathodic target can be extended about 0.2 inch, but this measurement can be extended from about 0.1 inch to about 0.25 inch from the original recess. Circled area 505 can be deepened further to trap condensed particles and to keep the edge temperature higher. FIG. 5B shows how the anodic shield 550 is placed relative to the cathodic target 540 in a contemplated design and how the primary arcing sites 560 are relocated. The relocation of the arcing sites keeps the arc induced particle projectiles from reaching the surface of a wafer or the target surface in the sputtering system.

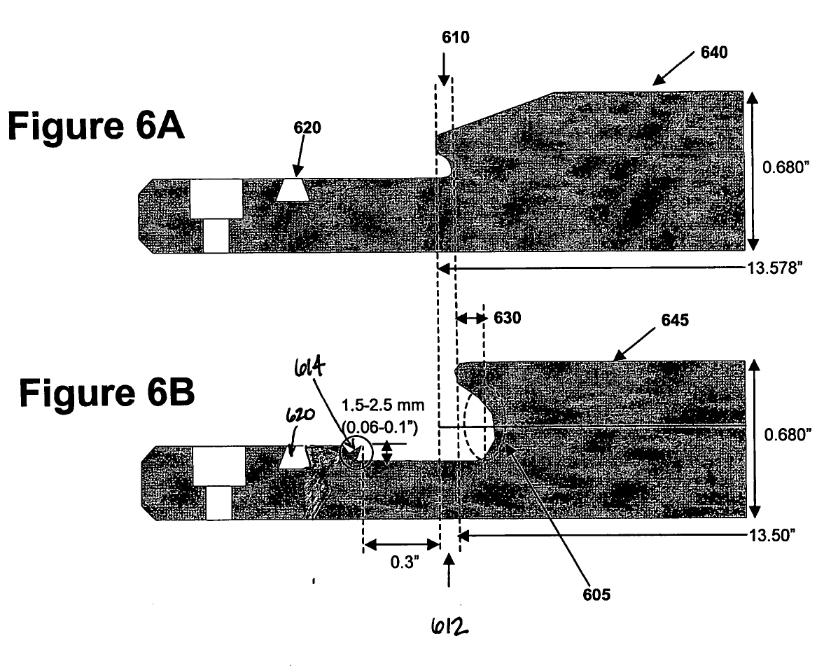

FIG. 6A shows a contemplated cathodic target design 640 having a vent slot 620 where a minimal recess 610 is incorporated into the design. The recess 610 in this embodiment is about 1 mm. FIG. 6B shows the modified target design 645. Measurements 630 show that the depth of the recess 612 for this embodiment can be extended about 0.15 inch, but this measurement can be up to about 0.25 inch for this embodiment. FIG. 6B also shows a protrusion 614. Circled area 605 can be deepened further to trap condensed particles and to keep the edge temperature higher. It should also be noted that in FIG. 6B, recess 612 is increased by about 1 mm or more or up to 3 mm from FIG. 6A. In addition, the depth of the trench can be deeper than 0.0625″ or as deep as the mechanical stability allows. The trench recess also can be greater than 0.2″ such that strike-arc induced particle projectiles are not in line-of-sight with the wafer.

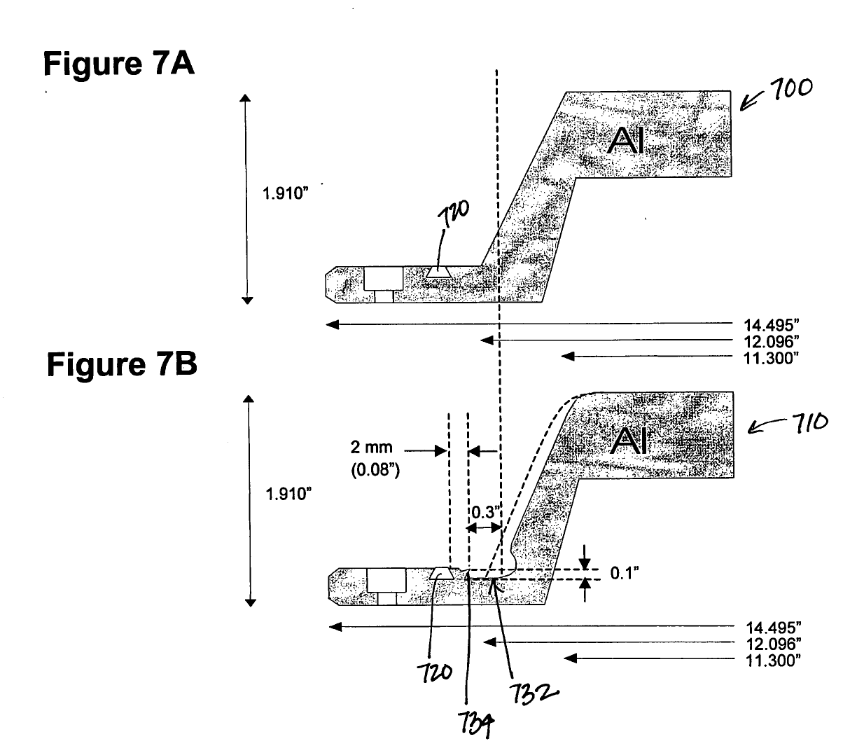

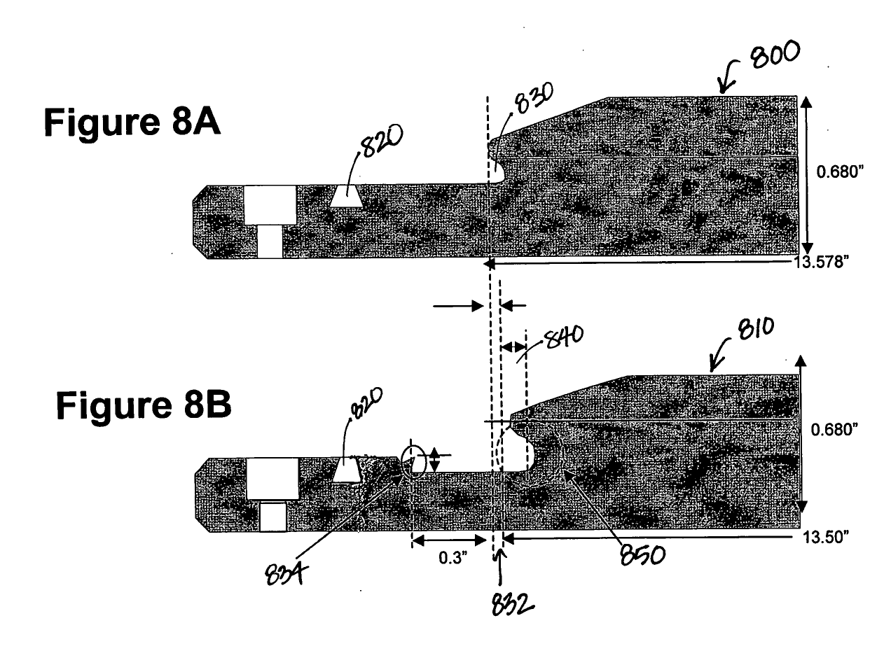

FIG. 7A shows a conventional ENDURA™ Al target 700 having a vent slot 720 and no recess and FIG. 7B shows a contemplated modification that will reduce arc-induced particle projectiles. The target 710 in FIG. 7B also comprises a vent slot 720, but also comprises a recess 732 and a protrusion 734. FIG. 8A shows another conventional target design 800 having a vent slot 820 and a conventional recess 830 that is about 1 mm in depth. FIG. 8B shows a modified target 810 also having a vent slot 820, a recess 832 and a protrusion 834, but this figure shows how a cavity and recess can be incorporated in order to reduce arc-induced particle projectiles. It should be noted that the recess 832 in FIG. 8B can be increased by about 1 mm or more, or up to about 3 mm. And the depth of trench can be deeper than 0.0625″ as far as mechanical stability allows. In FIG. 8B the recess 832 is extended 840 about 1.5 mm (0.0625 inch), but it may be extended further, if necessary. Circled area 850 can be deepened further to trap condensed particles and to keep the edge temperature higher. Also, circled area 835 shows that the corner of the recess in this embodiment should be made as sharp as possible.

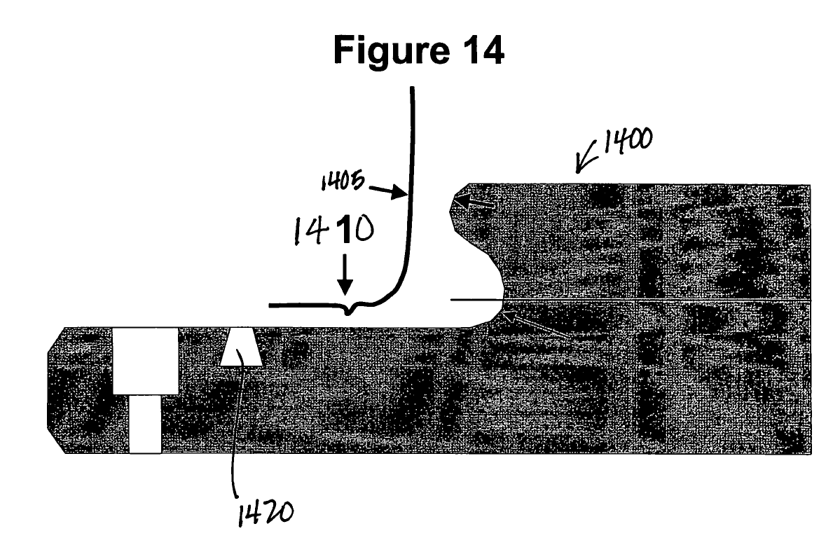

In these embodiments where the cathodic target comprises at least one recess, cavity or combination thereof and at least one protrusion, arc induced particle projectiles are directed away from the wafer surface by locating the initial arc site inside the recess or cavity or by locating the initial arc site where the protrusion has been formed. In some embodiments, protrusions may also be located or formed on the anodic shield 1405 in order to correspond with a protrusion or formation on or in the cathodic target 1400 having a vent slot 1420, such as the protrusion 1410 shown in FIG. 14. In these DC magnetron sputtering systems, the system comprises an anodic shield comprising at least one protrusion; a cathodic target comprising at least one recess, cavity or a combination thereof; and a plasma ignition arc, whereby the arc is located at the point of least resistance between the at least one protrusion coupled to the anodic shield and the at least one protrusion, recess or cavity. Experiments have shown that the plasma ignition arc will occur at the point of least resistance, typically the closest distance between the cathode (target) and anode (chamber shield) surfaces. This concept is similar to a spark plug in that it uses a electrical protrusion, or pin, as a point of highest electric potential field to start the plasma arc in a specific location. By locating the arc in a recess, cavity or combination thereof, the ejected projectiles can be directed away from the wafer surface. In some cases, such as a standard aluminum target, a simple pin can be located high on the side of the target sidewall such that projectiles are directed through a very narrow path that reduces the line of sight to the wafer.

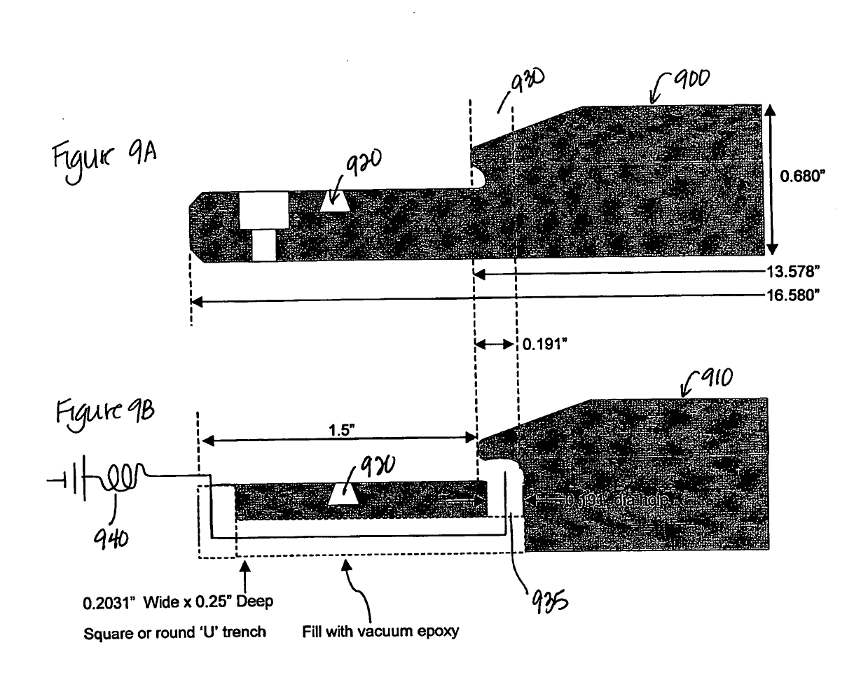

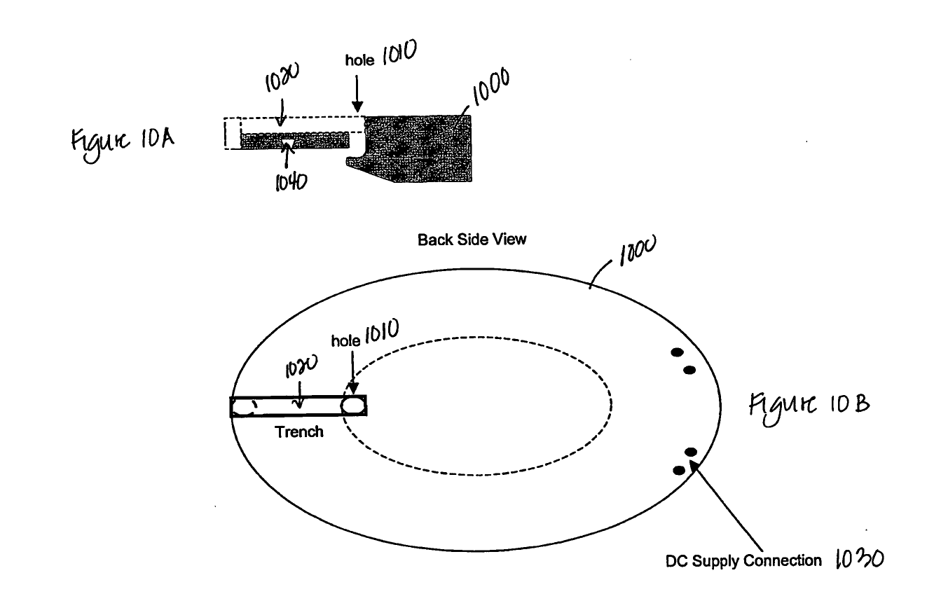

Alternatively, a recess can be made in the target and corresponding pins (protrusions) can be located on the target and shield, again to decrease projectile line of sight travel to the wafer. An ignition enclosure can be made, that uses target supply voltages in an enclosure which shields particles, and the ignition enclosure can be placed in the chamber. Another method is to use the target supply (or external voltage) to ignite an arc in a recess built into the target that will direct arc projectiles in a desired path away from the wafer or target surface. FIG. 9A shows a conventional IMP VECTRA™ Cu target design 900 having a vent slot 920 and a conventional recess 930. FIG. 9B shows a modified target design 910 having a vent slot 920 where an external voltage source 940 is embedded in the modified target recess 935. As mentioned, this external voltage will direct arc projectiles in a desired path away from the wafer or target surface. FIGS. 10A and 10B show additional perspective schematics of the cathodic target design 1000 having a trench 1020 with a hole 1010 and an external voltage source 1030. The vent slot 1040 is shown in FIG. 10A only.

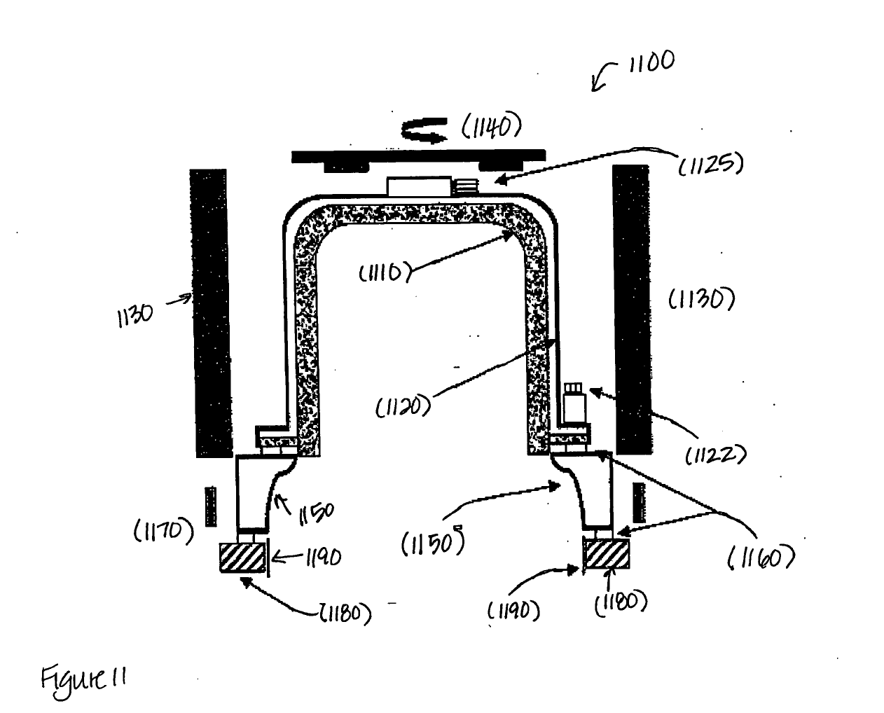

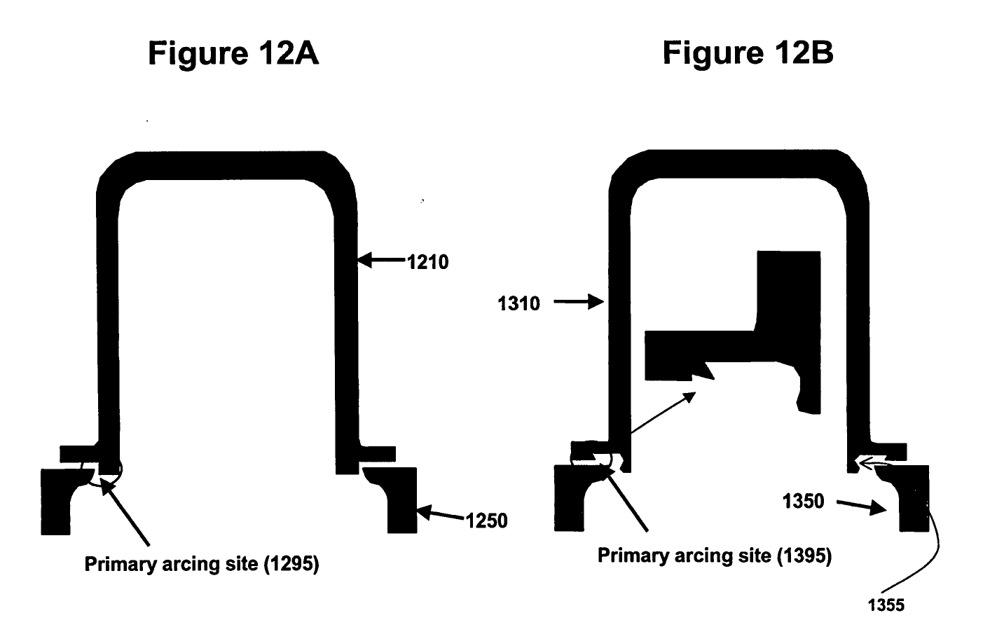

FIG. 11 shows a conventional HCM system 1100, as provided by Novellus Systems, Inc. As shown, target 1110 is surrounded by a water cooling jacket 1120, which has a water entrance 1122 and a water exit 1125. Fixed side magnets 1130 are located on both sides of the target 1110. A rotating magnet 1140 is located above the target 1110 and water cooling jacket 1120. Below the target 1110, a floating anode ring 1150 is supported by ceramic insulators 1160 and is surrounded by an eM coil 1170. An adapter ring 1180 and shield 1190 are located below the anode ring 1150. A simplified view of the HCM system is shown in FIG. 12A, where only the target 1210 and the anode ring 1250 is shown. The primary arcing site 1295 is shown in the circled area. FIG. 12B shows a modified target 1310, an anode ring 1350 and a particle collector groove 1355 with the primary arcing site 1395 shown in the circled area.

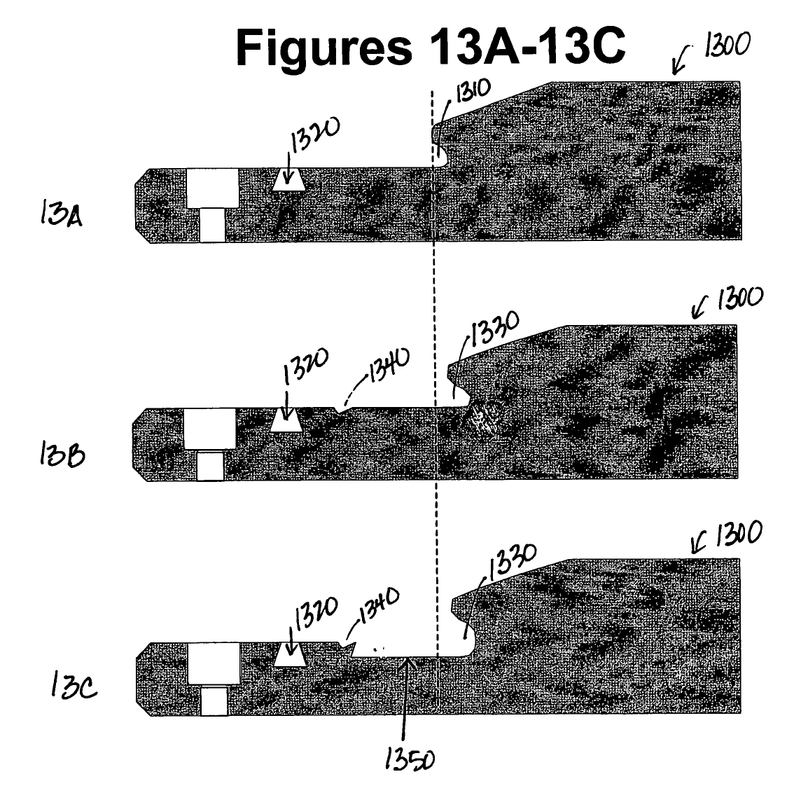

FIG. 13A-C shows one method of producing a protrusion in a modified target described herein, along with a recess. FIG. 13A shows a cathodic target 1300 having a vent slot 1320 where a minimal recess 1310 is incorporated into the design. FIG. 13B shows this same target 1300 where the original recess 1310 has been modified 1330 and a small slot 1340 has been machined into the target. FIG. 13C shows a cavity 1350 that has been machined into the target 1330 under the small slot 1340 and adjacent to the modified recess 1330 thereby forming the modified target.

In the contemplated embodiments described herein, the arc induced particle projectiles can be significantly reduced when compared to a conventional system, wherein the cathodic target and/or the anodic shield are not modified by including a catch ring system or a protrusion, recess, cavity or combination thereof. The conventional system, such as that shown in Prior Art FIG. 1, can be considered the “reference” or “control” meaning that the number of arc-induced particle projectiles produced in conventional systems should be the zero point by which all other modified systems are measured. In systems contemplated and described herein, the number of arc-induced particle projectiles are reduced by at least about 10%. In some systems, the number of arc-induced particle projectiles are reduced by at least about 25%. In other contemplated and described systems, the number of arc-induced particle projectiles are reduced by at least about 50%.

Methods are also provided whereby the gas turbulence effect is mitigated, such methods include providing an anodic shield; providing a cathodic target comprising at least one recess, cavity or a combination thereof and at least one protrusion; and initiating a plasma ignition arc, whereby the arc is located at the point of least resistance between the anodic shield and the at least one recess, cavity or a combination thereof, the at least one protrusion or a combination thereof. Additional methods include providing an anodic shield; providing a cathodic target that comprises at least one sidewall; providing a catch-ring coupled to and around the shield; and initiating a plasma ignition arc. Methods are also provided whereby the gas turbulence effect is mitigated, such methods include providing an anodic shield comprising at least one protrusion; providing a cathodic target comprising at least one recess, cavity or a combination thereof; and initiating a plasma ignition arc, whereby the arc is located at the point of least resistance between the at least one protrusion coupled to the anodic shield and the at least one protrusion, recess or cavity.

Other apparatus may be added to the DC magnetron sputtering systems described herein, such as coil sets. Contemplated coil sets may include those described in U.S. application Ser. No.: 11/086022 filed on Mar. 22, 2005, which is commonly-owned and incorporated herein in its entirety by reference.

Sputtering targets contemplated herein also comprise a surface material and a core material, wherein the surface material is coupled to the core material. The surface material is that portion of the target that is exposed to the energy source at any measurable point in time and is also that part of the overall target material that is intended to produce atoms that are desirable as a surface coating. As used herein, the term “coupled” means a physical attachment of two parts of matter or components (adhesive, attachment interfacing material) or a physical and/or chemical attraction between two parts of matter or components, including bond forces such as covalent and ionic bonding, and non-bond forces such as Van der Waals, electrostatic, coulombic, hydrogen bonding and/or magnetic attraction. The surface material and core material may generally comprise the same elemental makeup or chemical composition/component, or the elemental makeup and chemical composition of the surface material may be altered or modified to be different than that of the core material. In most embodiments, the surface material and the core material comprise the same elemental makeup and chemical composition. However, in embodiments where it may be important to detect when the target's useful life has ended or where it is important to deposit a mixed layer of materials, the surface material and the core material may be tailored to comprise a different elemental makeup or chemical composition.

The core material is designed to provide support for the surface material and to possibly provide additional atoms in a sputtering process or information as to when a target's useful life has ended. For example, in a situation where the core material comprises a material different from that of the original surface material, and a quality control device detects the presence of core material atoms in the space between the target and the wafer, the target may need to be removed and retooled or discarded altogether because the chemical integrity and elemental purity of the metal coating could be compromised by depositing undesirable materials on the existing surface/wafer layer. The core material is also that portion of a sputtering target that does not comprise macroscale modifications or microdimples, such as those disclosed in PCT Application Serial No.: PCT/US02/06146 and U.S. application Ser. No.: 10/672690, both of which are commonly-owned by Honeywell International Inc. and are incorporated herein in their entirety by reference. In other words, the core material is generally uniform in structure and shape.

The surface material is that portion of the target that is exposed to the energy source at any measurable point in time and is also that part of the overall target material that is intended to produce atoms and/or molecules that are desirable as a surface coating.

Sputtering targets, catch-rings and/or other related particle generation apparatus may generally comprise any material that can be a) reliably formed into a sputtering target, catch-rings and/or other related particle generation apparatus; b) sputtered from the target (and sometimes the coil) when bombarded by an energy source; and c) suitable for forming a final or precursor layer on a wafer or surface. It should be understood that although the catch-ring comprises materials that are considered the same or similar to those materials being sputtered, the catch-ring may or may not sputter atoms. Coil sputtering depends primarily on the coil bias with respect to the plasma and the wafer. Materials that are contemplated to make suitable sputtering targets, catch-rings and/or other related particle generation apparatus are metals, metal alloys, conductive polymers, conductive composite materials, conductive monomers, dielectric materials, hardmask materials and any other suitable sputtering material. As used herein, the term “metal” means those elements that are in the d-block and f-block of the Periodic Chart of the Elements, along with those elements that have metal-like properties, such as silicon and germanium. As used herein, the phrase “d-block” means those elements that have electrons filling the 3d, 4d, 5d, and 6d orbitals surrounding the nucleus of the element. As used herein, the phrase “f-block” means those elements that have electrons filling the 4f and 5f orbitals surrounding the nucleus of the element, including the lanthanides and the actinides. Preferred metals include titanium, silicon, cobalt, copper, nickel, iron, zinc, vanadium, ruthenium, zirconium, aluminum and aluminum-based materials, tantalum, niobium, tin, chromium, platinum, palladium, gold, silver, tungsten, molybdenum, cerium, promethium, thorium or a combination thereof. More preferred metals include copper, aluminum, ruthenium, tungsten, titanium, cobalt, tantalum, magnesium, lithium, silicon, manganese, iron or a combination thereof. Most preferred metals include copper, aluminum and aluminum-based materials, tungsten, titanium, zirconium, cobalt, ruthenium, tantalum, niobium or a combination thereof. Examples of contemplated and preferred materials, include aluminum and copper for superfine grained aluminum and copper sputtering targets; aluminum, copper, cobalt, tantalum, zirconium, and titanium for use in 200 mm and 300 mm sputtering targets, along with other mm-sized targets; and aluminum for use in aluminum sputtering targets that deposit a thin, high conformal “seed” layer of aluminum onto surface layers. It should be understood that the phrase “and combinations thereof” is herein used to mean that there may be metal impurities in some of the sputtering targets, such as a copper sputtering target with chromium and aluminum impurities, or there may be an intentional combination of metals and other materials that make up the sputtering target, such as those targets comprising alloys, borides, carbides, fluorides, nitrides, silicides, oxides and others. Materials contemplated herein also comprise those materials described in commonly-owned PCT Application Serial No.: PCT/US05/13663 entitled “Novel Ruthenium Alloys, Their Use in Vapor Deposition or Atomic Layer Deposition and Films Produced Therefrom”, which was filed on Apr. 21, 2005 and which is incorporated herein in its entirety by reference.

The term “metal” also includes alloys, metal/metal composites, metal ceramic composites, metal polymer composites, as well as other metal composites. Alloys contemplated herein comprise gold, antimony, arsenic, boron, copper, germanium, nickel, indium, palladium, phosphorus, silicon, cobalt, vanadium, iron, hafnium, titanium, iridium, zirconium, tungsten, silver, platinum, tantalum, tin, zinc, lithium, manganese, rhenium, and/or rhodium. Specific alloys include gold antimony, gold arsenic, gold boron, gold copper, gold germanium, gold nickel, gold nickel indium, gold palladium, gold phosphorus, gold silicon, gold silver platinum, gold tantalum, gold tin, gold zinc, palladium lithium, palladium manganese, palladium nickel, platinum palladium, palladium rhenium, platinum rhodium, silver arsenic, silver copper, silver gallium, silver gold, silver palladium, silver titanium, titanium zirconium, aluminum copper, aluminum silicon, aluminum silicon copper, aluminum titanium, chromium copper, chromium manganese palladium, chromium manganese platinum, chromium molybdenum, chromium ruthenium, cobalt platinum, cobalt zirconium niobium, cobalt zirconium rhodium, cobalt zirconium tantalum, copper nickel, iron aluminum, iron rhodium, iron tantalum, chromium silicon oxide, chromium vanadium, cobalt chromium, cobalt chromium nickel, cobalt chromium platinum, cobalt chromium tantalum, cobalt chromium tantalum platinum, cobalt iron, cobalt iron boron, cobalt iron chromium, cobalt iron zirconium, cobalt nickel, cobalt nickel chromium, cobalt nickel iron, cobalt nickel hafnium, cobalt niobium hafnium, cobalt niobium iron, cobalt niobium titanium, iron tantalum chromium, manganese iridium, manganese palladium platinum, manganese platinum, manganese rhodium, manganese ruthenium, nickel chromium, nickel chromium silicon, nickel cobalt iron, nickel iron, nickel iron chromium, nickel iron rhodium, nickel iron zirconium, nickel manganese, nickel vanadium, tungsten titanium and/or combinations thereof.

As far as other materials that are contemplated herein for sputtering targets, catch-rings and/or other related particle generation apparatus, the following combinations are considered examples of contemplated sputtering targets, coils and/or bosses (although the list is not exhaustive): chromium boride, lanthanum boride, molybdenum boride, niobium boride, tantalum boride, titanium boride, tungsten boride, vanadium boride, zirconium boride, boron carbide, chromium carbide, molybdenum carbide, niobium carbide, silicon carbide, tantalum carbide, titanium carbide, tungsten carbide, vanadium carbide, zirconium carbide, aluminum fluoride, barium fluoride, calcium fluoride, cerium fluoride, cryolite, lithium fluoride, magnesium fluoride, potassium fluoride, rare earth fluorides, sodium fluoride, aluminum nitride, boron nitride, niobium nitride, silicon nitride, tantalum nitride, titanium nitride, vanadium nitride, zirconium nitride, chromium silicide, molybdenum silicide, niobium silicide, tantalum silicide, titanium silicide, tungsten silicide, vanadium silicide, zirconium silicide, aluminum oxide, antimony oxide, barium oxide, barium titanate, bismuth oxide, bismuth titanate, barium strontium titanate, chromium oxide, copper oxide, hafnium oxide, magnesium oxide, molybdenum oxide, niobium pentoxide, rare earth oxides, silicon dioxide, silicon monoxide, strontium oxide, strontium titanate, tantalum pentoxide, tin oxide, indium oxide, indium tin oxide, lanthanum aluminate, lanthanum oxide, lead titanate, lead zirconate, lead zirconate-titanate, titanium aluminide, lithium niobate, titanium oxide, tungsten oxide, yttrium oxide, zinc oxide, zirconium oxide, bismuth telluride, cadmium selenide, cadmium telluride, lead selenide, lead sulfide, lead telluride, molybdenum selenide, molybdenum sulfide, zinc selenide, zinc sulfide, zinc telluride and/or combinations thereof.

Thin layers or films produced by the sputtering of atoms or molecules from targets discussed herein can be formed on any number or consistency of layers, including other metal layers, substrate layers, dielectric layers, hardmask or etchstop layers, photolithographic layers, anti-reflective layers, etc. In some preferred embodiments, the dielectric layer may comprise dielectric materials contemplated, produced or disclosed by Honeywell International, Inc. including, but not limited to: a) FLARE (polyarylene ether), such as those compounds disclosed in issued patents U.S. Pat. No. 5,959,157, U.S. Pat. No. 5,986,045, U.S. Pat. No. 6,124,421, U.S. Pat. No. 6,156,812, U.S. Pat. No. 6,172,128, U.S. Pat. No. 6,171,687, U.S. Pat. No. 6,214,746, and pending applications Ser. Nos. 09/197478, 09/538276, 09/544504, 09/741634, 09/651396, 09/545058, 09/587851, 09/618945, 09/619237, 09/792606, b) adamantane-based materials, such as those shown in pending application Ser. No. 09/545058; Serial PCT/US01/22204 filed Oct. 17, 2001; PCT/US01/50182 filed Dec. 31, 2001; 60/345374 filed Dec. 31, 2001; 60/347195 filed Jan. 8, 2002; and 60/350187 filed Jan. 15, 2002;, c) commonly assigned U.S. Pat. Nos. 5,115,082; 5,986,045; and 6,143,855; and commonly assigned International Patent Publications WO 01/29052 published Apr. 26, 2001; and WO 01/29141 published Apr. 26, 2001; and (d) nanoporous silica materials and silica-based compounds, such as those compounds disclosed in issued patents U.S. Pat. No. 6,022,812, U.S. Pat. No. 6,037,275, U.S. Pat. No. 6,042,994, U.S. Pat. No. 6,048,804, U.S. Pat. No. 6,090,448, U.S. Pat. No. 6,126,733, U.S. Pat. No. 6,140,254, U.S. Pat. No. 6,204,202, U.S. Pat. No. 6,208,014, and pending applications Ser. Nos. 09/046474, 09/046473, 09/111084, 09/360131, 09/378705, 09/234609, 09/379866, 09/141287, 09/379484, 09/392413, 09/549659, 09/488075, 09/566287, and 09/214219 all of which are incorporated by reference herein in their entirety and (e) Honeywell HOSP® organosiloxane.

The wafer or substrate may comprise any desirable substantially solid material. Particularly desirable substrates would comprise glass, ceramic, plastic, metal or coated metal, or composite material. In preferred embodiments, the substrate comprises a silicon or germanium arsenide die or wafer surface, a packaging surface such as found in a copper, silver, nickel or gold plated leadframe, a copper surface such as found in a circuit board or package interconnect trace, a via-wall or stiffener interface (“copper” includes considerations of bare copper and its oxides), a polymer-based packaging or board interface such as found in a polyimide-based flex package, lead or other metal alloy solder ball surface, glass and polymers such as polyimides. In more preferred embodiments, the substrate comprises a material common in the packaging and circuit board industries such as silicon, copper, glass, or a polymer.

The substrate layer may also comprise a plurality of voids if it is desirable for the material to be nanoporous instead of continuous. Voids are typically spherical, but may alternatively or additionally have any suitable shape, including tubular, lamellar, discoidal, or other shapes. It is also contemplated that voids may have any appropriate diameter. It is further contemplated that at least some of the voids may connect with adjacent voids to create a structure with a significant amount of connected or “open” porosity. The voids preferably have a mean diameter of less than I micrometer, and more preferably have a mean diameter of less than 100 nanometers, and still more preferably have a mean diameter of less than 10 nanometers. It is further contemplated that the voids may be uniformly or randomly dispersed within the substrate layer. In a preferred embodiment, the voids are uniformly dispersed within the substrate layer.

The surface provided is contemplated to be any suitable surface, as discussed herein, including a wafer, substrate, dielectric material, hardmask layer, other metal, metal alloy or metal composite layer, antireflective layer or any other suitable layered material. The coating, layer or film that is produced on the surface may also be any suitable or desirable thickness—ranging from one atom or molecule thick (less than 1 nanometer) to millimeters in thickness.

Wafers and layered materials (stacks) produced from the sputtering systems described herein can be incorporated into any process or production design that produces, builds or otherwise modifies electronic, semiconductor and communication/data transfer components. Electronic, semiconductor and communication components as contemplated herein, are generally thought to comprise any layered component that can be utilized in an electronic-based, semiconductor-based or communication-based product. Contemplated components comprise micro chips, circuit boards, chip packaging, separator sheets, dielectric components of circuit boards, printed-wiring boards, touch pads, wave guides, fiber optic and photon-transport and acoustic-wave-transport components, any materials made using or incorporating a dual damascene process, and other components of circuit boards, such as capacitors, inductors, and resistors.

Electronic-based, semiconductor-based and communications-based/data transfer-based products can be “finished” in the sense that they are ready to be used in industry or by other consumers. Examples of finished consumer products are a television, a computer, a cell phone, a pager, a palm-type organizer, a portable radio, a car stereo, and a remote control. Also contemplated are “intermediate” products such as circuit boards, chip packaging, and keyboards that are potentially utilized in finished products.

Electronic, semiconductor and communication/data transfer products may also comprise a prototype component, at any stage of development from conceptual model to final scale-up mock-up. A prototype may or may not contain all of the actual components intended in a finished product, and a prototype may have some components that are constructed out of composite material in order to negate their initial effects on other components while being initially tested.

Thus, specific embodiments and applications of the design and use of DC magnetron sputtering systems have been disclosed. It should be apparent, however, to those skilled in the art that many more modifications besides those already described are possible without departing from the inventive concepts herein. The inventive subject matter, therefore, is not to be restricted except in the spirit of the specification disclosed herein. Moreover, in interpreting the specification, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

We claim:

1. A DC magnetron sputtering system, comprising:
an anodic shield;
a cathodic target comprising at least one recess, cavity or a combination thereof and at least one protrusion; and
a plasma ignition arc, whereby the arc is located at the point of least resistance between the anodic shield and the at least one recess, cavity or combination thereof and the at least one protrusion.

2. The sputtering system of claim 1, wherein the location of the arc reduces arc induced particle projectiles by at least 10%.

3. The sputtering system of claim 2, wherein the location of the arc reduces arc induced particle projectiles by at least 25%.

4. The sputtering system of claim 3, wherein the location of the arc reduces arc induced particle projectiles by at least 50%.

5. The sputtering system of claim 1, wherein the anodic shield comprises at least one protrusion that corresponds to the at least one protrusion on the cathodic target.

6. A DC magnetron sputtering system, comprising:
an anodic shield comprising at least one protrusion;
a cathodic target comprising at least one recess, cavity or a combination thereof; and
a plasma ignition arc, whereby the arc is located at the point of least resistance between the at least one protrusion coupled to the anodic shield and the at least one protrusion, recess or cavity.

7. The sputtering system of claim 6, wherein the location of the arc reduces arc induced particle projectiles by at least 10%.

8. The sputtering system of claim 7, wherein the location of the arc reduces arc induced particle projectiles by at least 25%.

9. The sputtering system of claim 8, wherein the location of the arc reduces arc induced particle projectiles by at least 50%.

10. The sputtering system of claim 1, wherein the cathodic target also comprises at least one protrusion that corresponds to the at least one protrusion on the anodic shield.

11. A DC magnetron sputtering system, comprising:
an anodic shield;
a cathodic target that comprises at least one sidewall;
a plasma ignition arc; and
a catch-ring coupled to and around the shield.

12. The sputtering system of claim 11, wherein the plasma ignition arc produces a plurality of strike-arc induced particles.

13. The sputtering system of claim 12, wherein at least some of the plurality of strike-arc induced particles are located in a particle projectile path.

14. The sputtering system of claim 13, wherein the particle projectile path is located in the gap between the anodic shield and the sidewall of the cathodic target.

15. The sputtering system of claim 14, wherein the gap is about 1 mm.

16. The sputtering system of claim 11, wherein the location of the catch ring reduces arc induced particle projectiles by at least 10%.

17. The sputtering system of claim 16, wherein the location of the catch ring reduces arc induced particle projectiles by at least 25%.

18. The sputtering system of claim 17, wherein the location of the catch ring reduces arc induced particle projectiles by at least 50%.

19. The sputtering system of claim 11, wherein the width of the catch ring overlaps with the projection of the edge of the target.

20. The sputtering system of claim 19, wherein the width of the catch ring overlaps about 1 to about 3 mm with the projection of the edge of the target.

21. The sputtering system of claim 11, wherein the distance from the target to the catch ring is about 1 to about 2 cm.

22. A DC magnetron sputtering system of one of claims 1, 6 or 11 that further comprises a wafer.

23. The DC magnetron sputtering system of claim 22, wherein the wafer comprises a layer, film, layered material or stacked material.

24. An electronic component comprising the wafer of claim 23.

25. The DC magnetron sputtering system of claim 1, wherein an external voltage source is coupled to the cathodic target and terminates in the at least one recess, cavity or combination thereof or the at least one protrusion.

26. A method of mitigating the gas turbulence effect in a DC magnetron sputtering system, comprising:
providing an anodic shield;
providing a cathodic target comprising at least one recess, cavity or a combination thereof and at least one protrusion; and
initiating a plasma ignition arc, whereby the arc is located at the point of least resistance between the anodic shield and the at least one recess, cavity or a combination thereof and at least one protrusion or a combination thereof.

27. A method of mitigating the gas turbulence effect in a DC magnetron sputtering system, comprising:
providing an anodic shield;
providing a cathodic target that comprises at least one sidewall;
providing a catch-ring coupled to and around the shield; and
initiating a plasma ignition arc.
